(19) United States
(12) Patent Application Publication
(10) Pub. No.: US 2003/0137818 A1
(43) Pub. Date: Jul. 24, 2003

(54) Base for an electronic component

(75) Inventor: Shou-Kuen Chou, Taoyuan Hsien (TW)

Correspondence Address: BRUCE H. TROXELL, 5205 LEESBURG PIKE, SUITE 1404, FALLS CHURCH, VA, 22041, US

(73) Assignee: FERRICO CORPORATION

(21) Appl. No.: 10/179,221

(22) Filed: Jun. 26, 2002

(30) Foreign Application Priority Data
Jan. 21, 2002 (TW) 091200496

(51) Int. Cl. H05K 7/02; H05K 7/04

(52) U.S. Cl. 361/807

(57) ABSTRACT

A base for an electronic component is made of insulation material and a pair of oppositely disposed wire holes are defined in the base next to an edge of the base for being passed through with wound wires or contacts.

### BACKGROUND OF THE INVENTION

1. Field of the Invention

The present invention relates to a base for an electronic component, and, particularly, to improvement on the base for an electronic component.

2. Description of Related Art

Usually, electronic components are actuated by way of a circuit board and the circuit board is designed to have preset joints for joining with the electronic components. Because each of the electronic components is provided with contact pins or leading wires, the contact pins or leading wires are used for being joining to the preset joints to for open circuit. The so-called electronic components include resistors, capacitors, inductors and etc.

The electronic components generate high temperature during being actuated and it is only the contact pins connect with the joints so that each of the electronic components is provided with a base and the base is made of ceramics, which has a feature of the rmostabiity in addition to insulation.

Taking the inductor as an example, FIG. 1 shows a perspective view of a core thereof associated with a base. The iron core A is wound with fine lead wires and the lead wires entangle grooves D formed in two ears C respectively and then extend downward toward the bottom of the base. Two projections E are arranged at the bottom such that a gap between the base B and the circuit board can be formed for being soldered and adhered to each other.

Although the preceding conventional base for joining an electronic component has been used for many years and can perform the basic function thereof, the abrupt lugs C with grooves D make the base not possible to provide a smooth appearance. Further, the wound wires have to pass over the grooves D so that it is possible for the wires exposing themselves to other electronic component or becoming broken. Besides, it results in a problem of flatness at the bottom of the base B, that is, if the bottom projects downward beyond the projection E, the base B may be attached to the circuit board slantingly. An inclined base B on the circuit board may increase difficulty to the soldering or adhering job.

### SUMMARY OF THE INVENTION

Accordingly, an object of the present invention is to provide a base for an electronic component, which is made of insulation material and a pair of oppositely disposed wire holes are defined in the base next to the edge of the base for being passed through with wound wires or contacts.

### BRIEF DESCRIPTION OF THE DRAWINGS

The present invention can be more fully understood by reference to the following detailed description and accompanying drawings, in which:

FIG. 1 is a perspective view illustrating a conventional base with an electronic component;

FIG. 2 is a perspective view of a base for an electronic component according to the present invention; and

FIG. 3 is a sectional view of the base shown in FIG. 2 being associated with the electronic component.

### DETAILED DESCRIPTION OF THE PREFERRED EMBODIMENTS

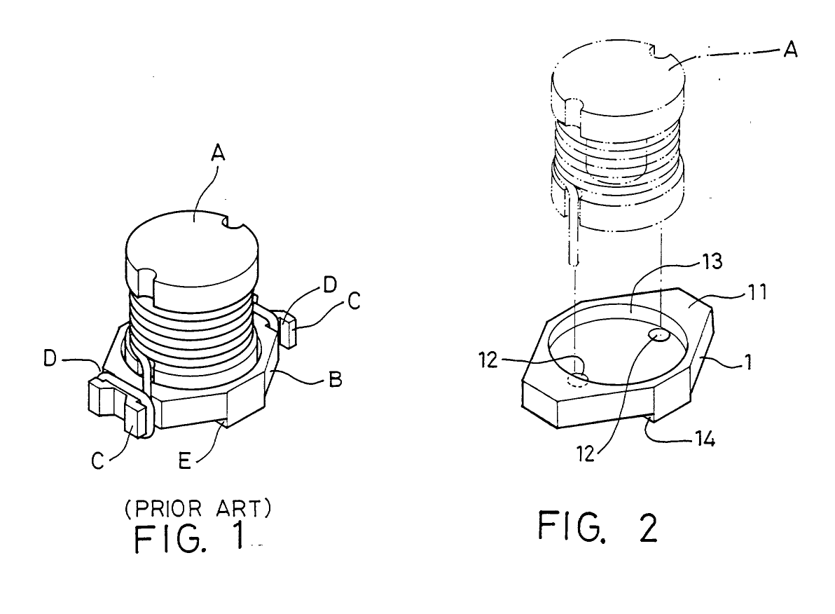

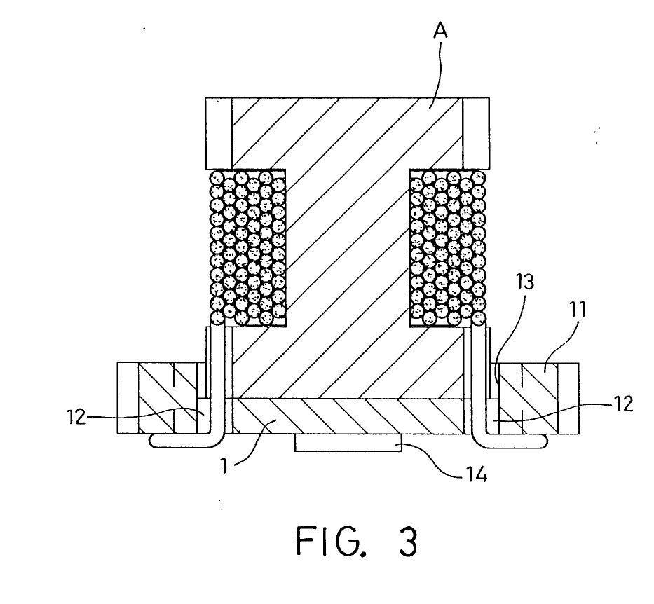

Referring to FIGS. 2 and 3, a base 1 for a electronic component is an integrated piece and it is preferable that the base 1 is made of ceramics. That is, it does not limit the material of the base 1 has to be ceramics so that the base 1 can be made of thermostable insulation material. The base can provide a shape complies with the electronic component. The base has a shape depending on the electronic component and it is preferable that the base is provided with a geometrical shape.

A great difference of the present invention from the conventional base is that the base 1 of the present invention has no the ear C with the groove D done in the conventional base and provides a pair of oppositely disposed wire holes 12. The wire holes 12 are pierced holes for being passed through with wires or terminals. Besides, the base at the periphery thereof has a plurality of annular projections or a circular ring edge 13 surrounding the periphery thereof. The annular projections and the circular ring edge 13 are prior art so that no detail will be described further. The base 1 at the bottom thereof extends downward at least two opposite projections 14. The projections 14 are belonged to known art so that no detail will be described further too.

Referring to FIG. 3 again, taking an inductor as an example, in case of the iron core in the inductor has been wound with wire, wire ends thereof can be arranged to pass through the wire holes 12 and then bent inward in a state of being flat. In this way, the wire ends can be taken in both the bottom and the projections 14 of the base. As soon as the base is attached with the inductor and is associated with the circuit board, the wire ends can be soldered or adhered to the circuit to form an open circuit instead of jutting outward on the projections 14 such that the projections 14 can be horizontal supports.

It is appreciated from the preceding description that a base for an electronic component according to the present invention allows the electronic component being placed on and joined to the circuit board evenly in addition to base being simplified. Further, the contacts or the wound wire on the electronic component can be soldered to the circuit board or adhered to the circuit board with other adhesives completely.

While the invention has been described with reference to the a preferred embodiment thereof, it is to be understood that modifications or variations may be easily made without departing from the spirit of this invention, which is defined by the appended claims.

What is claimed is:

1. A base for an electronic component, being made of insulation material; characterized in that a pair of oppositely disposed wire holes are defined in the base next to an edge of the base;
whereby, it is possible for winding wires or contact pins to pass through the base.

2. The base for an electronic component as defined in claim 1, wherein the base at the edge thereof projects an edge ring for the electronic component being located in place.

3. The base for an electronic component as defined in claim 1, wherein the base at a bottom thereof has a pair of oppositely disposed projections extending downward as supports.

4. The base for an electronic component as defined in claim 1, wherein the base is an integrated piece.

5. The base for an electronic component as defined in claim 1, wherein the base is an inductor.
